(19) United States
(12) Patent Application Publication
(10) Pub. No.: US 2008/0265381 A1
(43) Pub. Date: Oct. 30, 2008

(54) SiCOH DIELECTRIC

(75) Inventors: Ali Afzali-Ardakani, Ossining, NY (US); Stephen M. Gates, Ossining, NY (US); Alfred Grill, White Plains, NY (US); Deborah A. Neumayer, Danbury, CT (US); Son Nguyen, Yorktown Heights, NY (US); Vishnubhai V. Patel, Yorktown Heights, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 12/133,043

(22) Filed: Jun. 4, 2008

Related U.S. Application Data
(63) Continuation of application No. 11/336,726, filed on Jan. 20, 2006.

(51) Int. Cl. H01L 21/469; H01L 23/58

(52) U.S. Cl. 257/632; 438/781; 257/E21.273

(57) ABSTRACT

A porous composite material useful in semiconductor device manufacturing, in which the diameter (or characteristic dimension) of the pores and the pore size distribution (PSD) is controlled in a nanoscale manner and which exhibits improved cohesive strength (or equivalently, improved fracture toughness or reduced brittleness), and increased resistance to water degradation of properties such as stress-corrosion cracking, Cu ingress, and other critical properties is provided. The porous composite material is fabricating utilizing at least one bifunctional organic porogen as a precursor compound.

### RELATED APPLICATIONS

This application is a continuation of U.S. patent application Ser. No. 11/336,726, filed Jan. 20, 2006, which is related to co-assigned and co-pending U.S. patent application Ser. Nos. 11/040,778, filed Jan. 21, 2005, and 11/190,360, filed Jul. 27, 2005, the entire contents of each of the aforementioned U.S. patent applications are incorporated herein by reference.

### FIELD OF THE INVENTION

The present invention generally relates to a class of dielectric materials comprising Si, C, O and H atoms (SiCOH) that have a low dielectric constant (k), and methods for fabricating films of these materials and electronic devices containing such films. Such materials are also called C doped oxide (CDO) or organosilicate glass (OSG). The SiCOR dielectrics are fabricated using a bifunctional organic molecule as one of the precursors.

### BACKGROUND OF THE INVENTION

The continuous shrinking in dimensions of electronic devices utilized in ULSI circuits in recent years has resulted in increasing the resistance of the BEOL metallization as well as increasing the capacitance of the intralayer and interlayer dielectric. This combined effect increases signal delays in ULSI electronic devices. In order to improve the switching performance of future ULSI circuits, low dielectric constant (k) insulators, and particularly those with k significantly lower than silicon oxide, are needed to reduce the capacitances. Generally, the speed of an integrated microprocessor circuit can be limited by the speed of electrical signal propagation through the BEOL (back-end-of-the-line) interconnects. Ultralow k (ULK) dielectric materials having a dielectric constant of about 2.7 or less permit a BEOL interconnect structure to transmit electrical signals faster, with lower power loss, and with less cross-talk between metal conductors such as, for example, Cu. Porous materials typically have a dielectric constant that is less than the non-porous version of the same material. Typically, porous materials are usefull for a range of applications including, for example, as an interlevel or intralevel dielectric of an interconnect structure.

A typical porous dielectric material is comprised of a first solid phase and a second phase comprising voids or pores. The terms “voids” and “pores” are used interchangeably in the present application. A common aspect of porous materials is the problem of controlling the characteristic dimensions of the pores and the pore size distribution (PSD). The size and PSD have strong effects on the properties of the material. Specific properties that may be affected by the pores size or the PSD of a dielectric material include, for example, electrical, chemical, structural and optical. Also, the processing steps used in fabricating the BEOL interconnect structure can degrade the properties of an ULK dielectric, and the amount of degradation is dependant on the size of the pores in the ULK dielectric. The foregoing may be referred to as “processing damage”. The presence of large pores (larger than the maximum in the pore size distribution) leads to excessive processing damage because plasma species, water, and processing chemicals can move easily through large pores and can become trapped in the pores.

Typically, the pores in an ULK dielectric have an average size (i.e., majority of the pores) and also have a component of the PSD that is comprised of larger pores (on the order of a few nm) with a broad distribution of larger sizes due to pore connection as the pore density increases (i.e., minority population of larger pores).

The minority population of larger pores allows both liquid and gas phase chemicals to penetrate into the ULK film more rapidly. These chemicals are found in both wet and plasma treatments that are routinely used during integration of the ULK dielectric material to build an interconnect structure.

In view of the above, there is a need for providing composite materials in which all the pores within the composite material are small having a diameter of about 5 nm or less and with a narrow PSD. There is also need for providing a method of fabricating composite materials in which the broad distribution of larger sized pores is substantially eliminated from the material.

Key problems with prior art porous ultra low k SiCOH films include, for example: (a) they are brittle (i.e., low cohesive strength, low elongation to break, low fracture toughness); (b) liquid water and water vapor reduce the cohesive strength of the material even further. A plot of the cohesive strength, CS vs. pressure of water, P_{H2O} or % humidity, which is referred as a “CS humidity plot”, has a characteristic slope for each k value and material; (c) they tend to possess a tensile stress in combination with low fracture toughness, and hence tend to crack when in contact with water when the film is above some critical thickness; (d) they can absorb water and other process chemicals, which in turn can lead to enhanced Cu electrochemical corrosion under electric fields, and ingress into the porous dielectric leading to electrical leakage and high conductivity between conductors; and (e) when C is bound as Si—CH₃ groups, prior art SiCOH dielectrics readily react with resist strip plasmas, CMP processes, and other integration processes, causing the SiCOH dielectric to be “damaged” resulting in a more hydrophilic surface layer.

For example, the silicate and organosilicate glasses tend to fall on a universal curve of cohesive strength vs. dielectric constant as shown in FIG. 1. This figure includes conventional oxides (point A), conventional SiCOH dielectrics (point B), conventional k=2.6 SiCOH dielectrics (point C), and conventional CVD ultra low k dielectrics with k about 2.2 (point D). The fact that both quantities are predominantly determined by the volume density of Si—O bonds explains the proportional variation between them. It also suggests that OSG materials with ultra low dielectric constants (e.g., k<2.4) are fundamentally limited to having cohesive strengths about 3 J/m² or less in a totally dry environment. Cohesive strength is further reduced as the humidity increases.

Another problem with prior art SiCOH films is that their strength tends to be degraded by H₂O. The effects of H₂O degradation on prior art SiCOH films can be measured using a 4-point bend technique as described, for example, in M. W. Lane, X. H. Liu, T. M. Shaw, “Environmental Effects on Cracking and Delamination of Dielectric Films”, IEEE Transactions on Device and Materials Reliability, 4, 2004, pp. 142-147. FIG. 2A is taken from this reference, and is a plot illustrating the effects that H₂O has on the strength of a typical SiCOH film having a dielectric constant, k of about 2.9. The data are measured by the 4-point bend technique in a chamber in which the pressure of water (P_{H2O}) is controlled and changed. Specifically, FIG. 2A shows the cohesive strength plotted vs. natural log(ln) of the H₂O pressure in the controlled chamber. The slope of this plot is approximately −1 in the units used. Increasing the pressure of H₂O decreases the cohesive strength. The region above the line in FIG. 2A, which is shaded, represents an area of cohesive strength that is difficult to achieve with prior art SiCOH dielectrics.

FIG. 2B is also taken from the M. W. Lane reference cited above, and is similar to FIG. 2A. Specifically, FIG. 2B is a plot of the cohesive strength of another SiCOH film measured using the same procedure as FIG. 2A. The prior art SiCOH film has a dielectric constant of 2.6 and the slope of this plot is about −0.66 in the units used. The region above the line in FIG. 2B, which is shaded, represents an area of cohesive strength that is difficult to achieve with prior art SiCOH dielectrics.

It is known that Si—C bonds are less polar than Si—O bonds. Further, it is known that organic polymer dielectrics have a fracture toughness higher than organosilicate glasses and are not prone to stress corrosion cracking (as are the Si—O based dielectrics). This suggests that the addition of more organic polymer content and more Si—C bonds to SiCOH dielectrics can decrease the effects of water degradation described above and increase the nonlinear energy dissipation mechanisms such as plasticity. Addition of more organic polymer content to SiCOH will lead to a dielectric with increased fracture toughness and decreased environmental sensitivity.

It is known in other fields that mechanical properties of some materials, for example, organic elastomers, can be improved by certain crosslinking reactions involving added chemical species to induce and form crosslinked chemical bonds. This can increase the elastic modulus, glass transition temperature, and cohesive strength of the material, as well as, in some cases, the resistance to oxidation, resistance to water uptake, and related degradations.

Most of the fabrication steps of very-large-scale-integration (“VLSI”) and ULSI chips are carried out by plasma enhanced chemical or physical vapor deposition techniques. The ability to fabricate a low k material by a plasma enhanced chemical vapor deposition (PECVD) technique using previously installed and available processing equipment will thus simplify its integration in the manufacturing process, reduce manufacturing cost, and create less hazardous waste. U.S. Pat. Nos. 6,147,009 and 6,497,963 assigned to the common assignee of the present invention, which are incorporated herein by reference in their entirety, describe a low dielectric constant material consisting of elements of Si, C, O and H atoms having a dielectric constant not more than 3.6 and which exhibits very low crack propagation velocities.

Despite the numerous disclosures of SiCOH dielectrics, there is still a need for providing new and improved SiCOH dielectrics which utilize relative simple and cost effective processing techniques.

### SUMMARY OF THE INVENTION

The present invention provides a composite material useful in semiconductor device manufacturing, and more particular to porous composite materials in which the diameter (or characteristic dimension) of the pores and the pore size distribution (PSD) is controlled in a nanoscale manner and which exhibit improved cohesive strength (or equivalently, improved fracture toughness or reduced brittleness), and increased resistance to water degradation of properties such as stress-corrosion cracking, Cu ingress, and other critical properties. The term “nanoscale” is used herein to denote pores that are less than about 5 nm in diameter.

The present invention also provides a method of fabricating the porous composite materials of the present application as well as to the use of the inventive dielectric material as an intralevel or interlevel dielectric film, a dielectric cap and/or a hard mask/polish stop in back end of the line (BEOL) interconnect structures on ultra-large scale integrated (ULSI) circuits and related electronic structures. The present invention also relates to the use of the inventive dielectric material in an electronic device containing at least two conductors or an electronic sensing structure.

Specifically, the present invention provides a porous composite dielectric in which substantially all of the pores within the composite dielectric are small having a diameter of about 5 nm or less, preferably about 3 nm or less, and even more preferably about 1 nm or less, and with a narrow PSD. The term “narrow PSD” is used throughout the instant application to denote a measured pore size distribution with a full width at half maximum (FWHM) of about 1 to about 3 nm. PSD is measured using a common technique known in the art including, but not limited to: ellipsometric porosimetry (EP), positron annihilation spectroscopy (PALS), gas adsorption methods, X-ray scattering or another method.

The inventive composite material is also characterized by the substantial absence of a broad distribution of larger sized pores which is prevalent in prior art porous composite materials. The composite materials of the present invention represent an advancement over the prior art, in one aspect, since they do not allow wet chemicals to penetrate beyond the exposed surfaces of the material during a wet chemical cleaning process. Moreover, the composite materials of the present invention are an advancement over the prior art, in a second aspect, since they do not allow plasma treatments based on O₂, H₂, NH₃, H₂O, CO, CO₂, CH₃H, C₂H₅OH, noble gases and related mixtures of these gases to penetrate beyond the exposed surfaces of the material during integration thereof.

The composite material of the present invention comprises a low or ultra low k dielectric constant porous material comprising atoms of Si, C, O and H (hereinafter “SiCOH”) having a dielectric constant of not more than 2.7 (i.e., about 2.7 or less). Moreover, the inventive porous composite dielectric comprises a first solid phase having a first characteristic dimension and a second solid phase comprised of pores having a second characteristic dimension, wherein the composite dielectric has a pore size distribution with a full width at half maximum (FWHM) of about 1 to about 3 nm with an increased cohesive strength of not less than about 6 J/m², and preferably not less than about 7 J/m², as measured by channel cracking or a sandwiched 4 point bend fracture mechanics test.

The present invention also provides a porous SICOH dielectric having a covalently bonded three-dimensional network structure, which includes a fraction of C bonded as Si—R—Si, wherein R is —[CH₂]ₙ—, —[HC═CH]ₙ—, —[C≡C]ₙ—, or —[CH₂C═CH]ₙ—, where n is greater than or equal to 1, further R may be branched and may include a mixture of single and double bonds. In accordance with the present invention, the fraction of the total carbon atoms in the material that is bonded as Si—R—Si is typically between 0.01 and 0.49, in one preferred embodiment, the SiCOH dielectric includes Si—[CH₂]ₙ—Si wherein n is 1 or 3.

Moreover, the porous SiCOH dielectric material of the present invention is very stable towards H₂O vapor (humidity) exposure, including a resistance to crack formation in water. In some embodiments, the inventive SiCOH dielectric material has a dielectric constant of less than about 2.5, a tensile stress less than about 40 MPa, an elastic modulus greater than about 3 CPa, a cohesive strength greater than about 3 to about 6 J/m², a crack development velocity in water of not more than 1×10⁻¹⁰ m/sec for a film thickness of 3 microns, and a fraction of the C atoms are bonded in the functional group Si—CH₂—Si wherein the carbon fraction is from about to 0.05 to about 0.5, as measured by C solid state NMR and by FTIR.

In alternative embodiments of the present invention, there is carbon bonded as Si—CH₃ and also carbon bonded as Si—R—Si, where R can be different organic groups.

In all embodiments of the inventive material, improved C—Si bonding is a feature of the materials compared to the Si—CH₃ bonding characteristic of prior art SiCOH and pSiCOH dielectrics.

In addition to providing a porous composite material, the present invention also provides a method of fabricating the porous composite material. Specifically, and in broad terms, the method of the present invention comprises providing at least a first precursor and a second precursor into a reactor chamber, wherein at least one of said first or second precursors is a bifunctional organic porogen; depositing a film comprising a first phase and a second phase; and removing said porogen from said film to provide a porous composite material comprising a first solid phase having a first characteristic dimension and a second solid phase comprised of pores having at second characteristic dimension, wherein the characteristic dimensions of at least one of said phases is controlled to a value of about 5 nm or less.

Within the present invention, the porogen precursor is selected from a new and manufacturable class of bifunctional organic molecules, which include bifunctional organic compounds comprised of a linear, branched, cyclic or polycyclic hydrocarbon backbone consisting of —[CH₂]ₙ— where n is greater than or equal to 1, and only two functional groups selected from alkenes, alkynes, ethers, epoxides, aldehydes, ketones, amines, hydroxyls, alcohols, carboxylic acids, nitries, esters, azido and azo.

The use of bifunctional organic molecules facilitates the incorporation of decomposable hydrocarbons into the SiCOH material, while enabling the control of the pore size distribution. Additionally, selection of a bifunctional organic molecule leads to an increase of SiRSi linkages in the inventive film compared with prior art compounds. It is observed that the use of monofunctional organic porogens is known, but the applicants have discovered that the use of monofanctional organic porogens leads to difficulties in incorporating the decomposable hydrocarbons into the SiCOH matrix. By replacing the monofunctional organic porogens with a bifunctional organic porogen, an unexpected increase in hydrocarbon incorporation was observed.

The porous SiCOH dielectric material of the present invention has a response of cohesive strength to humidity such as is described in U.S. patent application Ser. No. 11/040,778. That is, the porous SiCOH dielectric material is characterized as (i) having a cohesive strength in a dry ambient, i.e., the complete absence of water, greater than about 3 J/m², (ii) having a cohesive strength greater than about 3 J/m² at a water pressure of 1570 Pa at 25° C. (50% relative humidity), or (iii) having a cohesive strength greater than about 2.1 J/m² at a water pressure of 1570 Pa at 25° C. The inventive SiCOH dielectrics have a weaker dependence of cohesive strength to the partial pressure of H₂O than prior art materials. Within the invention, this is achieved by incorporating Si—[CH₂]ₙ—Si type bonding, using the new and manufacturable set of porogen precursors, which may or may not exhibit nonlinear deformation behavior that further increases the mechanical strength of the material. The net result is a dielectric with cohesive strength in a dry ambient that is at least equal, but preferably, greater than a Si—O based dielectric with the same dielectric constant, and the inventive dielectric material has significantly reduced environmental sensitivity.

The present invention also provides PECVD methods for depositing and appropriate methods for curing the inventive SiCOR dielectric material, with the PECVD deposition based on the new and manufacturable set of porogen precursors.

The present invention also relates to electronic structures, in which the SiCOH dielectric material of the present invention may be used as the interlevel or intralevel dielectric, a capping layer, and/or as a hard mask/polish-stop layer in electronic structures. The inventive SiCOH dielectric can also be used in other electronic structures such as circuit boards or passive analogue devices. The inventive SiCOH dielectric film may also be used other electronic structures including a structure having at least two conductors and an optoelectronic sensing structure, for use in detection of light.

### BRIEF DESCRIPTION OF THE DRAWINGS

FIG. 1 is a universal curve of cohesive strength vs. dielectric constant showing prior art dielectrics.

FIGS. 2A-2B show the cohesive strength plotted vs. natural log(ln) of the H₂O pressure in a controlled chamber for prior art SiCOH dielectrics.

FIG. 3 is schematic of pore size distribution of the inventive material utilizing various bifunctional organic molecules, showing both adsorption and desorption values.

FIGS. 4-9B are pictorial representations (through cross sectional views) depicting various electronic structures that can include the inventive SiCOH dielectric.

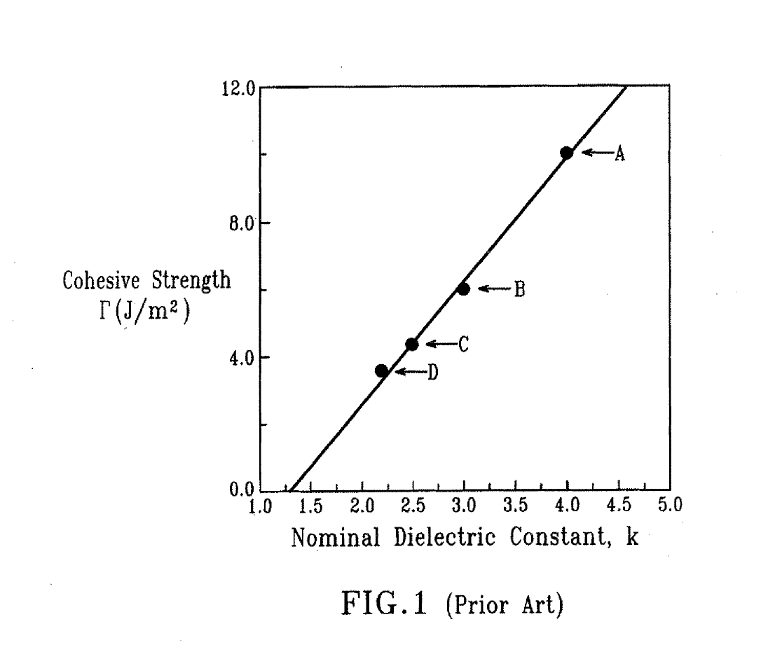

### DETAILED DESCRIPTION OF THE INVENTION

The present invention, which provides porous composite dielectric materials containing pores with pore size control on the nanometer scale as well as a method of fabricating the porous material, will now be described in greater detail by referring to the following discussion. In some embodiments of the present invention, drawings are provided to illustrate structures that include the porous composite dielectric materials of the present invention. In those drawings, the structures are not shown to scale.

The porous dielectric material of the present invention is made utilizing the methods described in U.S. Pat. Nos. 6,147,009, 6,312,793, 6,441,491, 6,437,443, 6,541,398, 6,479,110 B2, and 6,497,963, the contents of which are incorporated herein by reference. In the deposition process, the inventive porous dielectric material is formed by providing a mixture of at least two precursors, one of which includes the bifunctional organic molecule, into a reactor, preferably the reactor is a PECVD reactor, and then depositing a film derived from the mixture of precursors onto a suitable substrate (semiconducting, insulating, conductive or any combination or multilayers thereof) utilizing conditions that are effective in forming the porous dielectric material of the present invention. Within the present invention, correct choice of a bifunctional organic molecule enables the control of the pore size and PSD in the material.

The inventive bifunctional organic molecules are manufacturable and provide porosity and also provide a method to incorporate Si—R—Si bonding, wherein R is —[CH₂]ₙ—, —[HC═CH]ₙ—, —[C≡C]ₙ—, —[CH₂C═CH]ₙ—. This is accomplished using a bifunctional organic molecule of the general formula comprised of a linear, branched, cyclic or polycyclic hydrocarbon backbone of —[CH₂]ₙ—, where n is greater than or equal to 1, and is substituted at only two sites by a functional group selected from alkenes (—C═C—), alkynes (—C≡C—), ethers (—C—O—C—), 3 member oxiranes, epoxides, aldehydes (HC(O)—C—), ketones (—C—C(O)—C—), amines (—C—N—), hydroxyls (—OH), alcohols (—OR), carboxylic acids (—C(O)—O—H), nitrites (—C≡N), esters (—C(O)—C—), amino (—NH₂), azido (—N═N═N—) and azo (—N═N—). Within the invention, the hydrocarbon backbone may be linear, branched, or cyclic and may include a mixture of linear branched and cyclic hydrocarbon moieties. These organic groups are well known and have standard definitions that are also well known in the art. These organic groups can be present in any organic compound.

In a preferred embodiment, the functional groups are alkenes and the bifunctional organic molecule has the general formula [CH₂═CH]—[CH₂]ₙ—[CH═CH₂], where n is 1-8.

In a second preferred embodiment, the bifunctional organic molecule is selected from cyclopentene oxide, isobutylene oxide, 2,2,3-trimethyloxirane, butadienemonoxide, bicycloheptadiene, 1,2-epoxy-5-hexene and 2-methyl-2-vinyloxirane, propadiene, butadiene, pentadiene, hexadiene, heptadiene, octadiene, nonadiene, decadiene, cyclopentadiene, cyclohexadiene, dialkynes, such as propdiyne, butadiyne. The bifunctional organic molecule need not be symmetrical and can contain two different functional groups and can be cyclic or linear.

The mixture of at least two precursors contains at least a first organosilicon precursor, for example, consisting of a least one Si atom, an inert carrier such as He, Ar or mixtures thereof, and a second bifunctional organic molecule, for example, consisting of at least C and H. The present invention also contemplates embodiments where the first precursor is the bifunctional organic molecule and the second precursor is the organosilicon compound. Within the present invention, the second precursor comprises any Si containing compound including molecules selected from silane (SiH₄) derivatives having the molecular formulas SiR₄, disiloxane derivatives having the formula R₃SiOSiR₃, trisiloxane derivatives having the formulas R₃SiOSi R₂SiOSiR₃, cyclic Si containing compounds including cyclosiloxanes, cyclocarbosiloxanes cyclocarbosilane where the R substitutents may or may not be identical and are selected from H, alkyl, alkoxy, epoxy, phenyl, vinyl, allyl, alkenyl or alkynyl groups that may be linear, branched, cyclic, polycyclic and may be functionalized with oxygen, nitrogen or fluorine containing substituents, any cyclic Si containing compounds including cyclosiloxanes, cyclocarbosiloxanes.

Preferred silicon precursors include, but are not limited to: silane, methylsilane, dimethylsilane, trimethylsilane, tetramethylsilane, ethylsilane, diethylsilane, triethylsilane, tetraethylsilane, ethylmethylsilane, triethylmethylsilane, ethyldimethylsilane, ethyltrmethylsilane, diethyldimethylsilane, any alkoxysilane molecule, including, for example, diethoxymethylsilane (DEMS), dimethylethoxysilane, dimethyldimethoxysilane, tetramethylcyclotetrasiloxane (TMCTS), octamethylcyclotetrasiloxane (OMCTS), decamethylcyclopentasiloxane (DMCPS), ethoxyltrimethylsilane, ethoxydimethylsilane, dimethoxydimethylsilane, dimethoxymethylsilane, trimethoxymethylsilane, methoxysilane, dimethoxysilane, trimethoxysilane, tetramethoxysilane, ethoxysilane, diethoxysilane, triethoxysilane, tetraethoxysilane, methoxymethylsilane, dimethoxymethylsilane, trimethoxymethylsilane, methoxydimethylsilane, methoxytrimethylsilane, dimethoxyldimethylsilane, ethoxymethylsilane, ethoxydimethylsilane, ethoxytrimethylsilane, triethoxymethylsilane, diethoxydimethylsilane, ethylmethoxysilane, diethylmethoxysilane, triethylmethoxysilane, ethyldimethoxysilane, ethyltrimethoxysilane, diethyldimethoxysilane, ethoxymethylsilane, diethoxymethylsilane, triethoxymethylsilane, ethoxydimethylsilane, ethoxytrimethylsilane, diethoxyldimethylsilane, ethyldimethoxylmethylsilane, diethoxyethylmethylsilane, 1,3-disilolane, 1,1,3,3-tetramethoxy(ethoxy)-1,3-disilolane 1,1,3,3-tetramethyl-1,3-disilolane, vinylmethyldiethoxysilane (VDEMS), vinyltriethoxysilane, vinyldimethylethoxysilane, cyclohexenylethyltriethoxysilane, 1,1-diethoxy-1-silacyclopent-3-ene, divinyltetramethyldisiloxane, 2-(3,4-epoxycyclohexyl)ethyltriethoxysilane, 2-(3,4-epoxycyclohexyl)ethyltrimethoxysilane, epoxyhexyltriethoxysilane, hexavinyldisiloxane, trivinylmethoxysilane, trivinylethoxysilane, vinylmethylethoxysilane, vinylmethyldiethoxysilane, vinylmethyldimethoxysilane, vinylpentamethyldisiloxane, vinyltetramethyldisiloxane, vinyltriethoxysilane, vinyltrimethoxysilane, 1,1,3,3,-tetrahydrido-1,3-disilacyclobutane; 1,1,3,3-tetramethoxy(ethoxy)-1,3 disilacyclobutane; 1,3-dimethyl-1,3-dimethoxy-1,3 disilacyclobutane; 1,3-disilacyclobutane; 1,3-dimethyl-1,3-dihydrido-1,3-disilylcyclobutane; 1,1,3,3, tetramethyl-1,3-disilacyclobutane; 1,1,3,3,5,5-hexamethoxy-1,3,5-trisilane; 1,1,3,3,5,5-hexahydrido-1,3,5-trisilane; 1,1,3,3,5,5-hexamethyl-1,3,5-trisilane; 1,1,1,3,3,3-hexamethoxy(ethoxy)-1,3-disilapropane; 1,1,3,3-tetramethoxy-1-methyl-1,3-disilabutane; 1,1,3,3-tetramethoxy-1,3-disilapropane; 1,1,1,3,3,3-hexahydrido-1,3-disilapropane; 3-(1,1-dimethoxy-1-silaethyl)-1,4,4-trimethoxy-1-methyl-1,4-disilpentane; methoxymethane 2-(dimethoxysilamethyl)-1,1,4-trimethoxy-1,4-disilabutane; methoxymethane 1,1,4-trimethoxy-1,4-disila-2-(trimethoxysilylmethyl)butane; dimethoxymethane, methoxymethane; 1,1,1,5,5,5-hexamethoxy-1,5-disilapentane; 1,1,5,5-tetramethoxy-1,5-disilahexane; 1,1,5,5-tetramethoxy-1,5-disilapentane; 1,1,1,4,4,4-hexamethoxy(ethoxy)-1,4-disilybutane, 1,1,1,4,4,4,-hexahydrido-1,4-disilabutane; 1,1,4,4-tetramethoxy(ethoxy)-1,4-dimethyl-1,4-disilabutane; 1,4-bis-trimethoxy (ethoxy)silyl benzene; 1,4-bis-dimethoxymethylsilyl benzene; and 1,4-bis-trihydrosilyl benzene. Also the corresponding meta substituted isomers, such as, 1,1,1,4,4,4-hexamethoxy(ethoxy)-1,4-disilabut-2-ene; 1,1,1,4,4,4-hexamethoxy(ethoxy)-1,4-disilabut-2-yne; 1,1,3,3-tetramethoxy(ethoxy)-1,3-disilolane 1,3-disilolane; 1,1,3,3-tetramethyl-1,3-disilolane; 1,1,3,3-tetramethoxy(ethoxy)-1,3-disilane; 1,3-dimethoxy(ethoxy)-1,3-dimethyl-1,3-disilane; 1,3-disilane; 1,3-dimethoxy-1,3-disilane; 1,1-dimethoxy(ethoxy)-3,3-dimethyl-1-propyl-3-silabutane; 2-silapropane, 1,3-disilacyclobutane, 1,3-disilapropane, 1,5-disilapentane, or 1,4-bis-trihydrosilyl benzene.

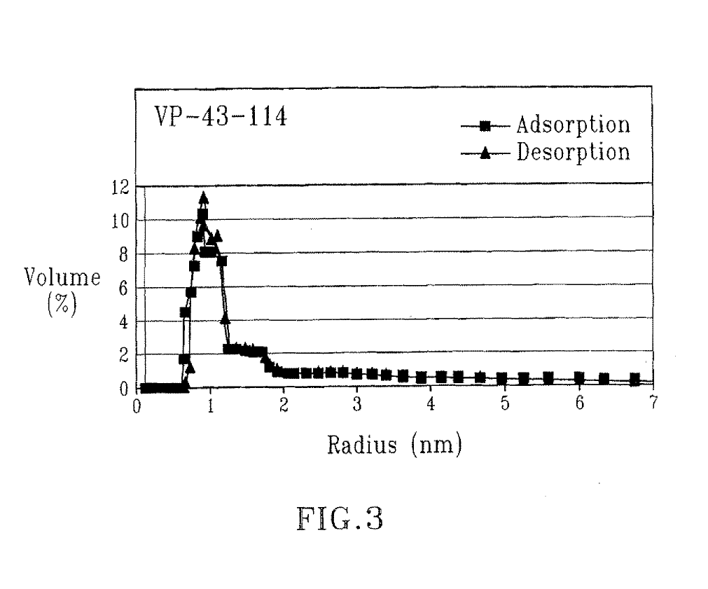

In addition to the first precursor, a second bifunctional organic molecule is used, such as a hydrocarbon with two double bonds (i.e., a diene). The size of the bifunctional organic molecule is adjusted in order to adjust the typical dimension of the pores (the size of the maximum in the PSD). Referring to FIG. 3, this drawing shows the result obtained using hexadiene as the second precursor. Preferred bifunctional organic molecules include propadiene, butadiene, pentadiene, hexadiene, heptadiene, octadiene, nonadiene, decadiene, cyclopentadiene, cyclohexadiene, dialkynes, such as propdiyne, butadiyne. The bifunctional organic molecule need not be symmetrical and can contain two different functional groups.

The present invention yet further provides for optionally adding an oxidizing agent such as O₂, N₂O, CO₂ or a combination thereof to the gas mixture, thereby stabilizing the reactants in the reactor and improving the properties and uniformity of the porous dielectric material being deposited.

The method of the present invention may further comprise the step of providing a parallel plate reactor, which has an area of a substrate chuck from about 85 cm² to about 750 cm², and a gap between the substrate and a top electrode from about 1 cm to about 12 cm. A high frequency RF power is applied to one of the electrodes at a frequency from about 0.45 MHz to about 200 MHz. Optionally, an additional RF power of lower frequency than the first RF power can be applied to one of the electrodes.

The conditions used for the deposition step may vary depending on the desired final dielectric constant of the porous dielectric material of the present invention. Broadly, the conditions used for providing a stable porous dielectric material comprising elements of Si, C, O, H, and having a tensile stress of less than 60 MPa, an elastic modulus from about 2 to about 15 GPa, and a hardness from about 0.2 to about 2 GPa include: setting the substrate temperature within a range from about 100° C. to about 425° C.; setting the high frequency RF power density within a range from about 0.1 W/cm² to about 2.0 W/cm²; setting the first liquid precursor flow rate within a range from about 10 mg/min to about 5000 mg/min, setting the second liquid precursor flow rate within a range from about 10 mg/min to about 5,000 mg/min; optionally setting the inert carrier gases, such as helium (or/and argon) flow rate within a range from about 10 sccm to about 5000 sccm; setting the reactor pressure within a range from about 1000 mTorr to about 10,000 mTorr; and setting the high frequency RF power within a range from about 50 W to about 1000 W. Optionally, a lower frequency power may be added to the plasma within a range from about 20 W to about 400 W. When the conductive area of the substrate chuck is changed by a factor of X, the RF power applied to the substrate chuck is also changed by a factor of X. When an oxidizing agent is employed in the present invention, it is flowed into the reactor at a flow rate within a range from about 10 sccm to about 1000 sccm.

While liquid precursors are used in the above example, it is known in the art that the organosilicon gas phase precursors (such as trimethylsilane) can also be used for the deposition. Optionally, after the as deposited film is prepared, a cure or treatment step may be applied to the film, according to the details described below.

An example of the first method of the present invention is now described to make the inventive SiCOH material: A 300 mm or 200 mm substrate is placed in a PECVD reactor on a heated wafer chuck at 300°-425° C. and preferably at 350°-400° C. Any PECVD deposition reactor may be used within the present invention. Gas and liquid precursor flows are then stabilized to reach a pressure in the range from 1-10 Torr, and RF radiation is applied to the reactor showerhead for a time from about 5 to about 500 seconds. For the growth of the material, either one or two precursors may be used, as described in U.S. Pat. Nos. 6,147,009, 6,312,793, 6,441,491, 6,437,443, 6,541,398, 6,479,110 B2, and 6,497,963, the contents of which are incorporated herein by reference. The first precursor may be DEMS (diethoxymethylsilane) or any of the above mentioned first precursors.

The second precursor is a bifunctional porogen used to prepare films with pore size controlled on the scale of about 1 nanometer. Within the invention, the bifunctional porogen produces hydrocarbon radicals in the PECVD plasma with a limited distribution of sizes of radicals. This is preferably achieved by choosing porogens containing two C═C double bond (known as dienes), so the radicals in the plasma have at most two primary reactive sites.

Within the invention, other hydrocarbon molecules with two reactive sites (including, for example, hydroxyls, alcohols, strained rings, ethers, etc.) may be used. Examples of preferred nanoscale porogens are butadiene, pentadiene, hexadiene, heptadiene, octadiene, and other linear or cyclic dienes containing two C═C double bonds.

Further, the inventive porogen molecules are manufacturable because these molecules are very stable for long times when held at temperatures near the boiling point. The inventive porogens do not polymerize at these temperatures, even when traces of O₂, H₂O, and other oxidizing species are present.

After deposition, the as deposited material is typically cured or treated using thermal, UV light, electron beam irradiation, chemical energy, or a combination of more than one of these, forming the final film having the desired mechanical and other properties described herein. For example, after deposition a treatment of the dielectric film (using both thermal energy and a second energy source) may be performed to stabilize the film and obtain improved properties. The second energy source may be electromagnetic radiation (UV, microwaves, etc.), charged particles (electron or ion beam) or may be chemical (using atoms of hydrogen, or other reactive gas, formed in a plasma). This treatment is also used to remove the porogen from the as deposited dielectric film.

In a preferred treatment, the substrate containing the film deposited according to the above process is placed in a ultraviolet (UV) treatment tool, with a controlled environment (vacuum or reducing environment containing H₂, or an ultra pure inert gas with a low O₂ and H₂O concentration). A pulsed or continuous UV source may be used, a substrate temperature of 300°-450° C. may be used, and at least one UV wavelength in the range of 170-400 nm may be used. UV wavelengths in the range of 190-300 nm are preferred within the invention.

Within the invention, the UV treatment tool may be connected to the deposition tool (“clustered”), or may be a separate tool. Thus, as is known in the art, the two process steps will be conducted within the invention in two separate process chambers that may be clustered on a single process tool, or the two chambers may be in separate process tools (“declustered”).

As stated above, the present invention provides dielectric materials (porous or dense, i.e., non-porous) that comprise a matrix of a hydrogenated oxidized silicon carbon material (SiCOH) comprising elements of Si, C, O and H in a covalently bonded three-dimensional network and have a dielectric constant of about 2.7 or less. The term “three-dimensional network” is used throughout the present application to denote a SiCOH dielectric material which includes silicon, carbon, oxygen and hydrogen that are interconnected and interrelated in the x, y, and z directions.

The present invention provides a porous SiCOH dielectric materials that have a covalently bonded three-dimensional network structure which includes C bonded as Si—CH₃ and also C bonded as Si—R—Si, wherein R is —[CH₂]ₙ—, —[HC═CH]ₙ—, —[C≡C]ₙ—, —[CH₂C═CH]ₙ—, where n is greater than or equal to 1, further R may be branched and may include a mixture of single and double bonds. In accordance with the present invention, the fraction of the total carbon atoms in the material that is bonded as Si—R—Si is typically between 0.01 and 0.99, as determined by solid state NMR. In one preferred embodiment, the SiCOH dielectric includes Si—[CH₂]ₙ—Si wherein n is 1 or 3. In the preferred embodiment, the total fraction of carbon atoms in the material that is bonded as Si—CH₂—Si is between 0.05 and 0.5, as measured by solid state NMR.

The SiCOH dielectric material of the present invention comprises between about 5 and about 40, more preferably from about 10 to about 20, atomic percent of Si; between about 5 and about 50, more preferably from about 15 to about 40, atomic percent of C; between 0 and about 50, more preferably from about 10 to about 30, atomic percent of 0; and between about 10 and about 55, more preferably from about 20 to about 45, atomic percent of H.

In some embodiments, the SiCOH dielectric material of the present invention may further comprise F and/or N. In yet another embodiment of the present invention, the SiCOH dielectric material may optionally have the Si atoms partially substituted by Ge atoms. The amount of these optional elements that may be present in the inventive dielectric material of the present invention is dependent on the amount of precursor that contains the optional elements that is used during deposition.

The SiCOH dielectric material of the present invention contains molecular scale voids (i.e., nanometer-sized pores) between about 0.3 to about 10 nanometers in diameter, and most preferably between about 0.4 and about 5 nanometers in diameter, which further reduce the dielectric constant of the SiCOH dielectric material. The nanometer-sized pores occupy a volume between about 0.5% and about 50% of a volume of the material.

The inventive SiCOH dielectric of the present invention has more carbon bonded in organic groups bridging between two Si atoms compared to the Si—CH₃ bonding characteristic of prior art SiCOH and pSiCOH dielectrics.

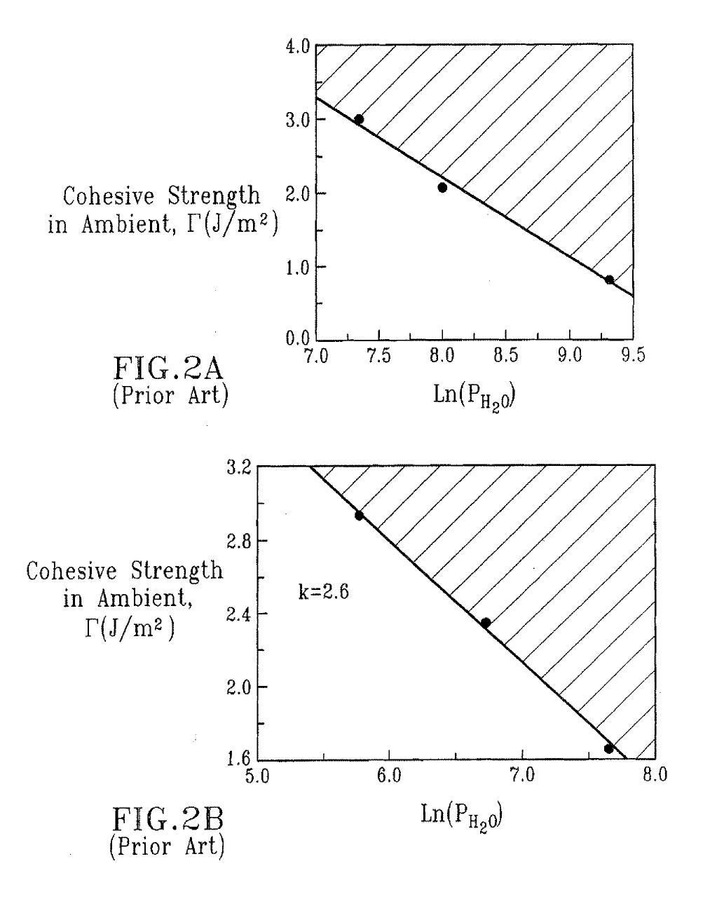

In addition to the aforementioned properties, the SiCOH dielectric materials of the present invention are hydrophobic with a water contact angle of greater than 70°, more preferably greater than 80° and exhibit a cohesive strength in shaded regions of FIGS. 2A and 2B.

The inventive SiCOH dielectric materials are typically deposited using plasma enhanced chemical vapor deposition (PECVD). In addition to PECVD, the present invention also contemplates that the SiCOH dielectric materials can be formed utilizing chemical vapor deposition (CVD), high-density plasma (HDP), pulsed PECVD, spin-on application, or other related methods.

The following are examples illustrating material and processing embodiments of the present invention.

### EXAMPLE 1

### SiCOH Material A

In this example, an inventive SiCOH dielectric, referred to as SiCOH film A, was made in accordance with the present invention. In this example, MDES stands for methoxydiethylsilane and HXD stands for hexadiene. A substrate was placed on a substrate holder in the reactor. Gas or liquid precursors, comprising a single organosilicon precursor and a second bifunctional organic porogen, were introduced in a PECVD reactor. In one example this reactor was a parallel plate reactor, while in another example it was a high density plasma reactor. After the flow of the precursor and the pressure in the reactor had stabilized at a preset conditions, RF power was applied to one or both electrodes of the reactor to dissociate the precursor and deposit a film on the substrate. The deposited film contained a SiCOH phase and an interconnected organic phase called the porogen (derived from the organic molecule functionality). The film was subsequently exposed to a treatment step, in which high energy breaks the organic phase (porogen) from the organosilicon matrix and caused the removal of the porogen from the film, thus creating a porous film with an ultralow dielectric constant (k), with k not more than 2.6, and preferably about 2.2-2.4. The energy used for the dissociation and removal of the porogen can be thermal (temperature up to 450° C.), electron beam, optical radiation, such as UV, laser. The removal of the porogen was typically associated with additional crosslinking of the film.

| MDES + HXD | Gas flow | Power W | K |
|---|---|---|---|
| SiCOH A | 1 + 5 | 30 | 1.94 |
| VP-43-101A43 | 1 + 3 | 25 | 2.03 |
| VP-43-108A43 | 2 + 2 | 25 | 2.345 |
| VP-43-109A43 | 2 + 2 | 30 | 2.466 |
| VP-43-110A43 | 4 + 2 | 40 | 2.50 |
| VP-43-112A43 | 2.4 | 30 | 2.26 |

### EXAMPLE 2

### First Process Embodiment

For the growth of a porous SiCOH material with k less than 2.7 having a pore size distribution full width at half maximum of about 1 to 3 n, and having enhanced Si—CH₂—Si bridging methylene carbon, two precursors were used, specifically hexadiene and DEMS (diethoxymethylsilane). Within the invention, any alkoxysilane precursor may be used in place of DEMS, including but not limited to: OMCTS, TMCTS, VDEMS, or dimethyldmethoxysilane.

As is known in the art, gases such as O₂ may be added, and He may be replaced by gases such as Ar, CO₂, or another noble gas.

The conditions used include a DEMS flow of 2000 mg/m, a hexadiene flow of 100 to 1000 mg/m, and a He gas flow of 1000 sccm, said flows were stabilized to reach a reactor pressure of 6 Torr. The wafer chuck was set at 350° C., and the high frequency RF power of 470 W was applied to the showerhead, and the low frequency RF (LRF) power was 0 W so that no LRF was applied to the substrate. The film deposition rate was about 2,000-4,000 Angstrom/second.

As is known in the art, each of the above process parameters may be adjusted within the scope of invention described above. For example, different RF frequencies including, but not limited to, 0.26, 0.35, 0.45 MHz, may also be used in the present invention. Also for example, an oxidizer such as O₂, or alternative oxidizers including N₂O, CO, or CO₂ may be used. Specifically, the wafer chuck temperature may be lower, for example, to 150°-350° C.

While hexadiene is the preferred bifunctional organic porogen which in combination with DEMS provides an enhanced fraction of Si—CH₂—Si bridging methylene carbon, other bifunctional organic porogens as described above may be used. In alternate embodiments, the conditions are adjusted to produce SiCOH films with dielectric constant from 1.8 up to 2.7.

In the above examples, the precursors are described having methoxy and ethoxy substituent groups, but these may be replaced by hydrido or methyl groups, and a carbosilane molecule containing a mixture of methoxy, ethoxy, hydrido and methyl substituent groups may be used within the invention.

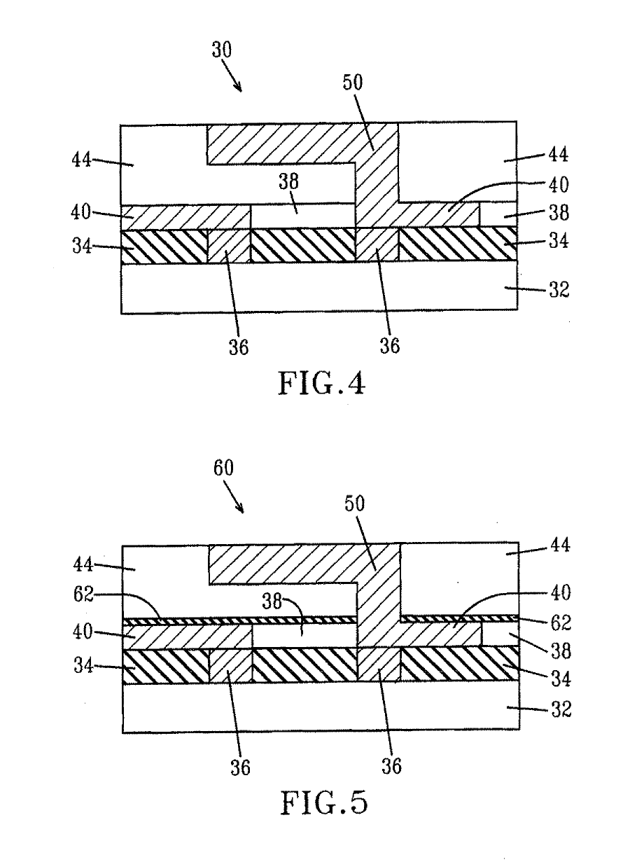

The electronic devices, which can include the inventive SiCOH dielectric, are shown in FIGS. 4-9B. It should be noted that the devices shown in FIGS. 4-9B are merely illustrative examples of the present invention, while an infinite number of other devices may also be formed by the present invention novel methods.

In FIG. 4, an electronic device 30 built on a silicon substrate 32 is shown. On top of the silicon substrate 32, an insulating material layer 34 is first formed with a first region of metal 36 embedded therein. After a CMP process is conducted on the first region of metal 36, a SiCOH dielectric film 38 of the present invention is deposited on top of the first layer of insulating material 34 and the first region of metal 36. The first layer of insulating material 34 may be suitably formed of silicon oxide, silicon nitride, doped varieties of these materials, or any other suitable insulating materials. The SiCOH dielectric film 38 is then patterned in a photolithography process followed by etching and a conductor layer 40 is deposited thereon. After a CMP process on the first conductor layer 40 is carried out, a second layer of the inventive SiCOH film 44 is deposited by a plasma enhanced chemical vapor deposition process overlying the first SiCOH dielectric film 38 and the first conductor layer 40. The conductor layer 40 may be deposited of a metallic material or a nonmetallic conductive material. For instance, a metallic material of aluminum or copper, or a nonmetallic material of nitride or polysilicon. The first conductor 40 is in electrical communication with the first region of metal 36.

A second region of conductor 50 is then formed after a photolithographic process on the SiCOH dielectric film 44 is conducted followed by etching and then a deposition process for the second conductor material. The second region of conductor 50 may also be deposited of either a metallic material or a nonmetallic material, similar to that used in depositing the first conductor layer 40. The second region of conductor 50 is in electrical communication with the first region of conductor 40 and is embedded in the second layer of the SiCOH dielectric film 44. The second layer of the SiCOH dielectric film 44 is in intimate contact with the first layer of SiCOH dielectric material 38. In this example, the first layer of the SiCOH dielectric film 38 is an intralevel dielectric material, while the second layer of the SiCOH dielectric film 44 is both an intralevel and an interlevel dielectric. Based on the low dielectric constant of the inventive SiCOH dielectric films, superior insulating property can be achieved by the first insulating layer 38 and the second insulating layer 44.

FIG. 5 shows a present invention electronic device 60 similar to that of electronic device 30 shown in FIG. 4, but with an additional dielectric cap layer 62 deposited between the first insulating material layer 38 and the second insulating material layer 44. The dielectric cap layer 62 can be suitably formed of a material such as silicon oxide, silicon nitride, silicon oxynitride, silicon carbide, silicon carbo-nitride (SiCN), silicon carbo-oxide (SiCO), and their hydrogenated compounds. The additional dielectric cap layer 62 functions as a diffusion barrier layer for preventing diffusion of the first conductor layer 40 into the second insulating material layer 44 or into the lower layers, especially into layers 34 and 32.

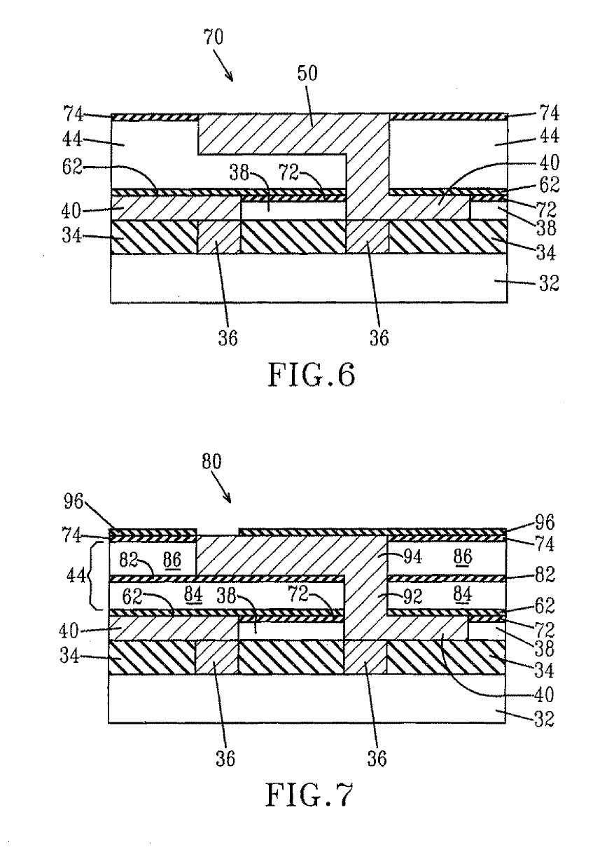

Another alternate embodiment of the present invention electronic device 70 is shown in FIG. 6. In the electronic device 70, two additional dielectric cap layers 72 and 74 which act as a RIE mask and CMP (chemical mechanical polishing) polish stop layer are used. The first dielectric cap layer 72 is deposited on top of the first ultra low k insulating material layer 38 and used as a RIE mask and CMP stop, so the first conductor layer 40 and layer 72 are approximately co-planar after CMP. The function of the second dielectric layer 74 is similar to layer 72, however layer 74 is utilized in planarizing the second conductor layer 50. The polish stop layer 74 can be deposited of a suitable dielectric material such as silicon oxide, silicon nitride, silicon oxynitride, silicon carbide, silicon carbo-oxide (SiCO), and their hydrogenated compounds. A preferred polish stop layer composition is SiCH or SiCOH for layers 72 or 74. A second dielectric layer can be added on top of the second SiCOH dielectric film 44 for the same purposes.

Still another alternate embodiment of the present invention electronic device 80 is shown in FIG. 7. In this alternate embodiment, an additional layer 82 of dielectric material is deposited and thus dividing the second insulating material layer 44 into two separate layers 84 and 86. The intralevel and interlevel dielectric layer 44 formed of the inventive ultra low k material is therefore divided into an interlayer dielectric layer 84 and an intralevel dielectric layer 86 at the boundary between via 92 and interconnect 94. An additional diffusion barrier layer 96 is further deposited on top of the upper dielectric layer 74. The additional benefit provided by this alternate embodiment electronic structure 80 is that dielectric layer 82 acts as an RIE etch stop providing superior interconnect depth control. Thus, the composition of layer 82 is selected to provide etch selectivity with respect to layer 86.

Still other alternate embodiments may include an electronic structure which has layers of insulating material as intralevel or interlevel dielectrics in a wiring structure that includes a pre-processed semiconducting substrate which has a first region of metal embedded in a first layer of insulating material, a first region of conductor embedded in a second layer of the insulating material wherein the second layer of insulating material is in intimate contact with the first layer of insulating material, and the first region of conductor is in electrical communication with the first region of metal, a second region of conductor in electrical communication with the first region of conductor and is embedded in a third layer of insulating material, wherein the third layer of insulating material is in intimate contact with the second layer of insulating material, a first dielectric cap layer between the second layer of insulating material and the third layer of insulating material and a second dielectric cap layer on top of the third layer of insulating material, wherein the first and the second dielectric cap layers are formed of a material that includes atoms of Si, C, O and H, or preferably a SiCOH dielectric film of the present invention.

Still other alternate embodiments of the present invention include an electronic structure which has layers of insulating material as intralevel or interlevel dielectrics in a wiring structure that includes a pre-processed semiconducting substrate that has a first region of metal embedded in a first layer of insulating material, a first region of conductor embedded in a second layer of insulating material which is in intimate contact with the first layer of insulating material, the first region of conductor is in electrical communication with the first region of metal, a second region of conductor that is in electrical communication with the first region of conductor and is embedded in a third layer of insulating material, the third layer of insulating material is in intimate contact with the second layer of insulating material, and a diffusion barrier layer formed of the dielectric film of the present invention deposited on at least one of the second and third layers of insulating material.

Still other alternate embodiments include an electronic structure which has layers of insulating material as intralevel or interlevel dielectrics in a wiring structure that includes a pre-processed semiconducting substrate that has a first region of metal embedded in a first layer of insulating material, a first region of conductor embedded in a second layer of insulating material which is in intimate contact with the first layer of insulating material, the first region of conductor is in electrical communication with the first region of metal, a second region of conductor in electrical communication with the first region of conductor and is embedded in a third layer of insulating material, the third layer of insulating material is in intimate contact with the second layer of insulating material, a reactive ion etching (RIE) hard mask/polish stop layer on top of the second layer of insulating material, and a diffusion barrier layer on top of the RIE hard mask/polish stop layer, wherein the RIE hard mask/polish stop layer and the diffusion barrier layer are formed of the SiCOH dielectric film of the present invention.

Still other alternate embodiments include an electronic structure which has layers of insulating materials as intralevel or interlevel dielectrics in a wiring structure that includes a pre-processed semiconducting substrate that has a first region of metal embedded in a first layer of insulating material, a first region of conductor embedded in a second layer of insulating material which is in intimate contact with the first layer of insulating material, the first region of conductor is in electrical communication with the first region of metal, a second region of conductor in electrical communication with the first region of conductor and is embedded in a third layer of insulating material, the third layer of insulating material is in intimate contact with the second layer of insulating material, a first RIE hard mask, polish stop layer on top of the second layer of insulating material, a first diffusion barrier layer on top of the first RIE hard mask/polish stop layer, a second RIE hard mask/polish stop layer on top of the third layer of insulating material, and a second diffusion barrier layer on top of the second RIE hard mask/polish stop layer, wherein the RIE hard mask/polish stop layers and the diffusion barrier layers are formed of the SiCOH dielectric film of the present invention.

Still other alternate embodiments of the present invention includes an electronic structure that has layers of insulating material as intralevel or interlevel dielectrics in a wiring structure similar to that described immediately above but further includes a dielectric cap layer which is formed of the SiCOH dielectric material of the present invention situated between an interlevel dielectric layer and an intralevel dielectric layer.

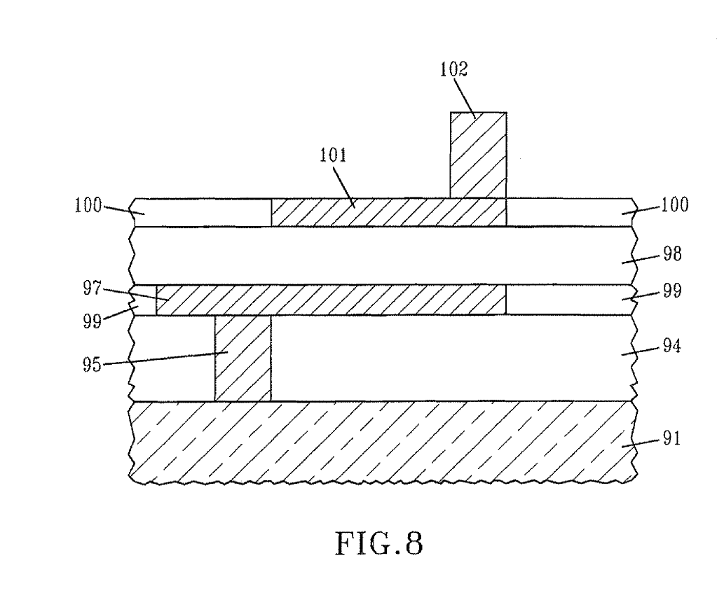

In some embodiments as shown, for example in FIG. 8, an electronic structure containing at least two metallic conductor elements (labeled as reference numerals 97 and 101) and a SiCOH dielectric material (labeled as reference numeral 98). Optionally, metal contacts 95 and 102 are used to make electrical contact to conductors 97 and 101. Reference numeral 91 denotes a substrate and 94 and 99 denote insulating materials including the SiCOH dielectric of the present invention. The inventive SiCOH dielectric 98 provides electrical isolation and low capacitance between the two conductors. The electronic structure is made using a conventional technique that is well known to those skilled in the art such as described, for example, in U.S. Pat. No. 6,737,727, the entire content of which is incorporated herein by reference.

The at least two metal conductor elements are patterned in a shape required for a function of a passive or active circuit element including, for example, an inductor, a resistor, a capacitor, or a resonator.

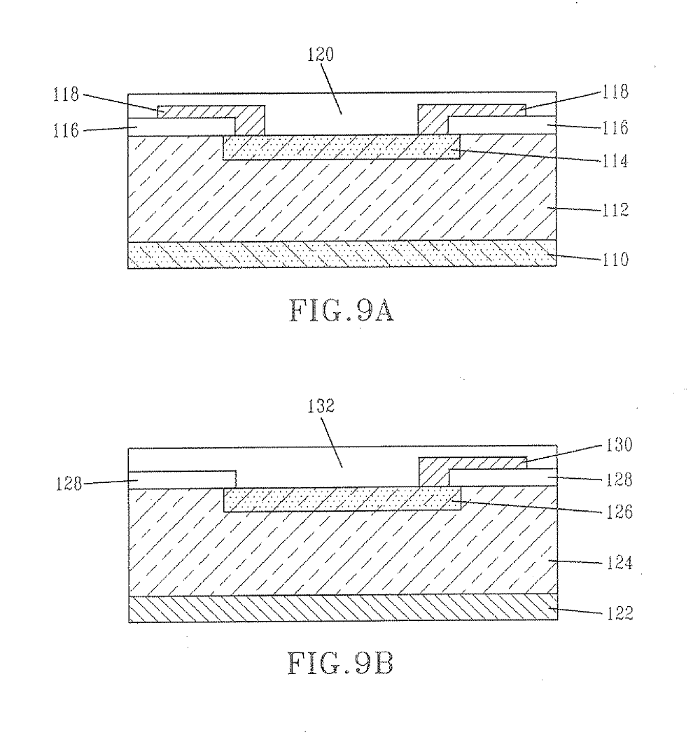

Additionally, the inventive SiCOH can be used in an electronic sensing structure wherein the optoelectronic sensing element (detector) shown in FIG. 9A or 9B is surrounded by a layer of the inventive SiCOH dielectric material. The electronic structure is made using a conventional technique that is well known to those skilled in the art. Referring to FIG. 9A, a p-i-n diode structure is shown which can be a high speed Si based photodetector for IR signals. The n+ substrate is 110, and atop this is an intrinsic semiconductor region 112, and within region 112 p+ regions 114 are formed, completing the p-i-n layer sequence. Layer 116 is a dielectric (such as SiO₂) used to isolate the metal contacts 118 from the substrate. Contacts 118 provide electrical connection to the p+ regions. The entire structure is covered by the inventive SiCOH dielectric material, 120. This material is transparent in the IR region, and serves as a passivation layer.

A second optical sensing structure is shown in FIG. 9B, this is a simple p-n junction photodiode, which can be a high speed IR light detector. Referring to FIG. 9B, the metal contact to substrate is 122, and atop this is an n-type semiconductor region 124, and within this region p+ regions 126 are formed, completing the p-n junction structure. Layer 128 is a dielectric (such as SiO₂) used to isolate the metal contacts 130 from the substrate. Contacts 130 provide electrical connection to the p+ regions. The entire structure is covered by the inventive SiCOH dielectric material, 132. This material is transparent in the IR region, and serves as a passivation layer.

While the present invention has been described in an illustrative manner, it should be understood that the terminology used is intended to be in a nature of words of description rather than of limitation. Furthermore, while the present invention has been described in terms of a preferred and several alternate embodiments, it is to be appreciated that those skilled in the art will readily apply these teachings to other possible variations of the invention.

What is claimed is:

1. A dielectric material comprising atoms of Si, C, O, and H and having a covalently bonded tri-dimensional random network structure in which a fraction of the C atoms are bonded as Si—CH₃ functional groups, and another fraction of the C atoms are bonded as Si—R—Si, wherein R is —[CH₂]ₙ—, —[HC═CH]ₙ—, —[C≡C]ₙ—, or —[CH₂C═CH]ₙ—, where n is greater than or equal to and the fraction of the total carbon atoms in the material that is bonded as Si—R—Si is between 0.01 and 0.49, wherein said material is a porous composite material comprising a first solid phase having a first characteristic dimension and a second phase comprised of pores having a second characteristic dimension, wherein the characteristic dimensions of at least one of said phases is controlled to a value of about 5 nm or less.

2. A method of forming a dielectric material comprising atoms of Si, C, O, and H comprising:
depositing a dielectric film comprising a first phase and a second phase onto a substrate utilizing at least a first precursor and a second precursor, wherein at least one of said first or second precursors is a bifunctional organic molecule forming a porogen in the film; and
removing said porogen from said dielectric film to provide a porous dielectric material comprising a first solid phase having a first characteristic dimension and a second solid phase comprised of pores having at second characteristic dimension, wherein the characteristic dimensions of at least one of said phases is controlled to a value of about 5 nm or less.

3. The method of claim 2 wherein said bifunctional organic molecule is comprised of a linear, branched, cyclic or polycyclic hydrocarbon backbone of —[CH₂]ₙ—, where n is greater than or equal to 1, and is substituted at only two sites by a functional group selected from alkenes, alkynes, ethers, 3 member oxiranes, epoxides, aldehydes, ketones, amines, hydroxyls, alcohols, carboxylic acids, nitriles, esters, amino, azido and azo.

4. The method of claim 3 wherein the functional groups are alkenes and the bifunctional organic molecule has the general formula [CH₂═CH]—[CH₂]ₙ—[CH═CH₂], where n is 1-8.

5. The method of claim 2 wherein said bifunctional organic molecule is one of cyclopentene oxide, isobutylene oxide, 2,2,3-trimethyloxirane, butadienemonoxide, bicycloheptadiene, 1,2-epoxy-5-hexene and 2-methyl-2-vinyloxirane, propadiene, butadiene, pentadiene, hexadiene, heptadiene, octadiene, nonadiene, decadiene, cyclopentadiene, cyclohexadiene, dialkynes, butadiene, pentadiene, hexadiene, heptadiene, octadiene, nonadiene, decadiene, cyclopentadiene, cyclohexadiene, propdiyne, butadiyne, diethers, diepoxides, dialdehydes, diketones, diamines, dihydroxyls, dialcohols, dicarboxylic acids, dinitriles, diesters, diazido, or diazo.

6. The method of claim 2 wherein one of said first or second precursors is a silicon containing molecule selected from the group of silane (SiH₄) derivatives having the molecular formulas SiR₄, disiloxane derivatives having the formula R₃SiOSiR₃, trisiloxane derivatives having the formula R₃SiOSiR₂SiOSiR₃, cyclic siloxanes, and cyclic Si containing compounds wherein the R substitutents may or may not be identical and are selected from H, alkyl, alkoxy, epoxy, phenyl, vinyl, allyl alkenyl or alkynyl groups that may be linear, branched, cyclic, polycyclic and may be functionalized with oxygen, nitrogen or fluorine containing substituents.

7. The method of claim 6 wherein said organosilicon precursor is one of silane, methylsilane, dimethylsilane, trimethylsilane, tetramethylsilane, ethylsilane, diethylsilane, triethylsilane, tetraethylsilane, ethylmethylsilane, triethylmethylsilane, ethyldimethylsilane, ethyltrimethylsilane, diethyldimethylsilane, diethoxymethylsilane (DEMS), dimethylethoxysilane, dimethyldimethoxysilane, tetramethylcyclotetrasiloxane (TMCTS), octamethylcyclotetrasiloxane (OMCTS), ethoxyltrimethylsilane, ethoxydimethylsilane, dimethoxydimethylsilane, dimethoxymethylsilane, trimethoxymethylsilane, methoxysilane, dimethoxysilane, trimethoxysilane, tetramethoxysilane, ethoxysilane, diethoxysilane, triethoxysilane, tetraethoxysilane, methoxymethylsilane, dimethoxymethylsilane, trimethoxymethylsilane, methoxydimethylsilane, methoxytrimethylsilane, dimethoxyldimethylsilane, ethoxymethylsilane, ethoxydimethylsilane, ethoxytrimethylsilane, triethoxymethylsilane, diethoxydimethylsilane, ethylmethoxysilane, diethylmethoxysilane, triethylmethoxysilane, ethyldimethoxysilane, ethyltrimethoxysilane, diethyldimethoxysilane, ethoxymethylsilane, diethoxymethylsilane, triethoxymethylsilane, ethoxydimethylsilane, ethoxytrimethylsilane, diethoxyldimethylsilane, ethyldimethoxylmethylsilane, diethoxyethylmethylsilane, 1,3-disilolane, 1,1,3,3-tetramethoxy(ethoxy)-1,3-disilolane 1,1,3,3-tetramethyl-1,3-disilolane, vinylmethyldiethoxysilane, vinyltriethoxysilane, vinyldimethylethoxysilane, cyclohexenylethyltriethoxysilane, 1,1-diethoxy-1-silacyclopent-3-ene, divinyltetramethyldisiloxane, 2-(3,4-epoxyeyclohexyl)ethyltriethoxysilane, 2-(3,4-epoxycyclohexyl)ethyltrimethoxysilane, epoxyhexyltriethoxysilane, hexavinyldisiloxane, trivinylmethoxysilane, trivinylethoxysilane, vinylmethylethoxysilane, vinylmethyldiethoxysilane, vinylmethyldimethoxysilane, vinylpentamethyldisiloxane, vinyltetramethyldisiloxane, vinyltriethoxysilane, vinyltrimethoxysilane, 1,1,3,3,-tetrahydrido-1,3-disilacyclobutane; 1,1,3,3-tetramethoxy(ethoxy)-1,3 disilacyclobutane; 1,3-dimethyl-1,3-dimethoxy-1,3 disilacyclobutane; 1,3-disilacyclobutane, 1,3-dimethyl-1,3-dihydrido-1,3-disilylcyclobutane, 1,1,3,3, tetramethyl-1,3-disilacyclobutane, 1,1,3,3,5,5-hexamethoxy-1,3,5-trisilane, 1,1,3,3,5,5-hexahydrido-1,3,5-trisilane, 1,1,3,3,5,5-hexamethyl-1,3,5-trisilane, 1,1,1,3,3,3-hexamethoxy(ethoxy)-1,3-disilapropane, 1,1,3,3-tetramethoxy-1-methyl-1,3-disilabutane, 1,1,3,3-tetramethoxy-1,3-disilapropane, 1,1,1,3,3,3-hexahydrido-1,3-disilapropane, 3-(1,1-dimethoxy-1-silaethyl)-1,4,4-trimethoxy-1-methyl-1,4-disilpentane, methoxymethane 2-(dimethoxysilamethyl)-1,1,4-trimethoxy-1,4-disilabutane, methoxymethane 1,1,4-trimethoxy-1,4-disila-2-(trimethoxysilylmethyl)butane, dimethoxymethane, methoxymethane, 1,1,1,5,5,5-hexamethoxy-1,5-disilapentane, 1,1,5,5-tetramethoxy-1,5-disilahexane, 1,1,5,5-tetramethoxy-1,5-disilapentane, 1,1,1,4,4,4-hexamethoxy(ethoxy)-1,4-disilylbutane, 1,1,1,4,4,4,-hexahydrido-1,4-disilabutane, 1,1,4,4-tetramethoxy(ethoxy)-1,4-dimethyl-1,4-disilabutane, 1,4-bis-trimethoxy (ethoxy)silyl benzene, 1,4-bis-dimethoxymethylsilyl benzene, 1,4-bis-trihydrosilyl benzene, 1,1,1,4,4,4-hexamethoxy(ethoxy)-1,4-disilabut-2-ene, 1,1,1,4,4,4-hexamethoxy(ethoxy)-1,4-disilabut-2-yne, 1,1,3,3-tetramethoxy(ethoxy)-1,3-disilolane 1,3-disilolane, 1,1,3,3-tetramethyl-1,3-disilolane, 1,1,3,3-tetramethoxy(ethoxy)-1,3-disilane, 1,3-dimethoxy(ethoxy)-1,3-dimethyl-1,3-disilane, 1,3-disilane; 1,3-dimethoxy-1,3-disilane, 1,1-dimethoxy(ethoxy)-3,3-dimethyl-1-propyl-3-silabutane, 2-silapropane, 1,3-disilacyclobutane, 1,3-disilapropane, 1,5-disilapentane, or 1,4-bis-trihydrosilyl benzene.

8. The method of claim 2 wherein said removing said porogen comprises treating said dielectric film with at least one energy source which comprises a thermal energy source, UV light, electron beam, chemical, microwave or plasma.

9. The method of claim 8 wherein the at least one energy source is a UV light, that may be pulsed or continuous, and said step is performed at a substrate temperature from 3000° 450° C., and with light that includes at least a UV wavelength between 150-370 nm.

10. A method of forming a dielectric material including atoms of Si, C, O and H comprising:
depositing a dielectric film comprising a first phase and a second phase onto a substrate utilizing at least a first precursor and a second precursor, wherein at least one of said first or second precursors is a bifunctional organic molecule comprised of a linear, branched, cyclic or polycyclic hydrocarbon backbone of —[CH₂]ₙ—, where n is greater than or equal to 1, and is substituted at only two sites by a functional group selected from alkenes, alkynes, ethers, 3 member oxiranes, epoxides, aldehydes, ketones, amines, hydroxyls, alcohols, carboxylic acids, nitriles, esters, amino, azido and azo forming a porogen in the film; and
removing said porogen from said dielectric film to provide a porous composite material comprising a first solid phase having a first characteristic dimension and a second solid phase comprised of pores having at second characteristic dimension, wherein the characteristic dimensions of at least one of said phases is controlled to a value of about 5 nm or less.

11. The method of claim 10 wherein the bifunctional organic molecule has the general formula [CH₂═CH]—[CH₂]ₙ—[CH═CH₂], wherein n is 1-8 and the functional groups are alkenes.

12. The method of claim 10 wherein said bifunctional organic molecule is one of cyclopentene oxide, isobutylene oxide, 2,2,3-trimethyloxirane, butadienemonoxide, bicycloheptadiene, 1,2-epoxy-5-hexene and 2-methyl-2-vinyloxirane, propadiene, butadiene, pentadiene, hexadiene, heptadiene, octadiene, nonadiene, decadiene, cyclopentadiene, cyclohexadiene, dialkynes, butadiene, pentadiene, hexadiene, heptadiene, octadiene, nonadiene, decadiene, cyclopentadiene, cyclohexadiene, propdiyne, butadiyne, diethers, diepoxides, dialdehydes, diketones, diamines, dihydroxyls, dialcohols, dicarboxylic acids, dinitriles, diesters, diazido, or diazo.

13. The method of claim 10 wherein one of said first or second precursors is a silicon containing molecule selected from silane (SiH₄) derivatives having the molecular formulas SiR₄, disiloxane derivatives having the formula R₃SiOSiR₃, trisiloxane derivatives having the formula R₃SiOSiR₂SiOSiR₃, cyclic siloxanes, and cyclic Si containing compounds including cyclosiloxanes, cyclocarbosiloxanes cyclocarbosilanes wherein the R substitutents may or may not be identical and are selected from H, alkyl, alkoxy, epoxy, phenyl, vinyl, allyl, alkenyl or alkynyl groups that may be linear, branched, cyclic, polycyclic and may be functionalized with oxygen, nitrogen or fluorine containing substituents.

14. The method of claim 10 wherein said removing said porogen comprises treating said dielectric film with at least one energy source which comprises a thermal energy source, UV light, electron beam, chemical, microwave or plasma.

15. A method of forming a dielectric material including atoms of Si, C, O and H comprising:
depositing a dielectric film comprising a first phase and a second phase onto a substrate utilizing at least a first precursor and a second precursor, wherein at least one of said first or second precursors is a bifunctional organic molecule has the general formula [CH₂═CH]—[CH₂]ₙ—[CH═CH₂], wherein n is 1-8 and the functional groups are alkenes to form a porogen in said film; and
removing said porogen from said dielectric film to provide a porous composite material comprising a first solid phase having a first characteristic dimension and a second solid phase comprised of pores having at second characteristic dimension, wherein the characteristic dimensions of at least one of said phases is controlled to a value of about 5 nm or less.

16. The method of claim 15 wherein said bifunctional organic molecule is one of cyclopentene oxide, isobutylene oxide, 2,2,3-trimethyloxirane, butadienemonoxide, bicycloheptadiene, 1,2-epoxy-5-hexene and 2-methyl-2-vinyloxirane, propadiene, butadiene, pentadiene, hexadiene, heptadiene, octadiene, nonadiene, decadiene, cyclopentadiene, cyclohexadiene, dialkynes, butadiene, pentadiene, hexadiene, heptadiene, octadiene, nonadiene, decadiene, cyclopentadiene, cyclohexadiene, propdiyne, butadiyne, diethers.

17. The method of claim 15 wherein one of said first or second precursors is any silicon containing molecule selected from the group any Si containing compound including molecules selected from silane (SiH₄) derivatives having the molecular formulas SiR₄, disiloxane derivatives having the formula R₃SiOSiR₃, trisiloxane derivatives having the formula R₃SiOSiR₂SiOSi R₃, cyclic siloxanes, and cyclic Si containing compounds wherein the R substitutents may or may not be identical and are selected from H, alkyl, alkoxy, epoxy, phenyl, vinyl, allyl, alkenyl or alkynyl groups that may be linear, branched, cyclic, polycyclic and may be functionalized with oxygen, nitrogen or fluorine containing substituents.

18. The method of claim 15 wherein said removing said porogen comprises treating said dielectric film with at least one energy source which comprises a thermal energy source, UV light, electron beam, chemical, microwave or plasma.

19. The method of claim 18 wherein the at least one energy source is a UV light, that may be pulsed or continuous, and said step is performed at a substrate temperature from 300°-450° C., and with light that includes at least a UV wavelength between 150-370 nm.
